(19) United States
(12) Patent Application Publication
(10) Pub. No.: US 2013/0301227 A1
(43) Pub. Date: Nov. 14, 2013

(54) CIRCUIT MODULE AND METHOD OF MANUFACTURING SAME

(71) Applicant: Murata Manufacturing Co., Ltd., Nagaokakyo-shi (JP)

(72) Inventor: Koji KAWANO, Nagaokakyo-shi (JP)

(21) Appl. No.: 13/936,419

(22) Filed: Jul. 8, 2013

Related U.S. Application Data
(63) Continuation of application No. PCT/JP2011/078930, filed on Dec. 14, 2011.

(30) Foreign Application Priority Data
Jan. 27, 2011 (JP) 2011-014890

(51) Int. Cl. H05K 1/02; H05K 3/30

(52) U.S. Cl. CPC H05K 1/0218; H05K 3/30
USPC 361/748; 174/260; 29/832

(57) ABSTRACT

A circuit module having satisfactory isolation characteristics and a method of manufacturing the same are such that electronic components are mounted on a principal surface of a circuit substrate. An insulating layer covers the principal surface of the circuit substrate and the electronic components. A groove is disposed in a principal surface of the insulating layer. A shielding layer covers the principal surface of the insulating layer and the inner surface of the groove.

### BACKGROUND OF THE INVENTION

1. Field of the Invention

The present invention relates to a circuit module and a method of manufacturing the same and, more specifically, to a circuit module including a substrate and an electronic component mounted on the substrate.

2. Description of the Related Art

One known example of an invention relating to a traditional circuit module is a circuit module described in Japanese Unexamined Patent Application Publication No. 2008-288610. A method of manufacturing the circuit module described in Japanese Unexamined Patent Application Publication No. 2008-288610 will be described below with reference to FIG. 12. FIG. 12 illustrates a cross-sectional structure of a circuit module 500 described in Japanese Unexamined Patent Application Publication No. 2008-288610.

As illustrated in FIG. 12, the circuit module 500 includes a substrate 502, electronic components 504, a sealing resin layer 506, and a shielding layer 510. The substrate 502 is a multilayer substrate in which electric circuits are incorporated. Each of the electronic components 504 is a chip-type electronic component, such as a capacitor or inductor, mounted on a principal surface of the substrate 502. The sealing resin layer 506 is an insulating layer that covers the principal surface of the substrate 502 and the electronic component 504. The shielding layer 510 is a conductive resin that covers the principal surface and the side surface of the sealing resin layer 506 and is connected to a ground conductor inside the substrate 502. In the above-described circuit module 500, the inside of the circuit module 500 is shielded by the shielding layer 510, which is made of the conductive resin applied on the sealing resin layer 506. Thus, there is no need to include a metal case for shielding the inside of the circuit module 500. As a result, the size and height of the circuit module 500 can be reduced.

The circuit module 500 has a problem in that it is difficult to achieve and maintain satisfactory isolation characteristics. More specifically, the circuit module 500 can be used in a wireless communication module, for example. The wireless communication module has been complicated and highly integrated in recent years, and a wireless LAN circuit block, a Bluetooth (registered trademark) circuit block, and an FM circuit block may be incorporated in a single circuit module. In this case, the circuit blocks may be arranged adjacent to one another, or a high-frequency circuit block for wireless communication and a signal processing circuit block for processing a baseband signal may be arranged adjacent to each other. As described above, if circuit blocks for use in different frequency bands are adjacent to each other, a signal of one circuit block enters the other circuit block as noise, and the isolation characteristics between the circuit blocks decrease. In the adjacent circuit blocks, a magnetic field occurring in one circuit block enters the other circuit block, and the isolation characteristics between the circuit blocks decrease.

### SUMMARY OF THE INVENTION

Accordingly, preferred embodiments of the present invention provide a circuit module having satisfactory isolation characteristics and a method of manufacturing the same.

A circuit module according to a preferred embodiment of the present invention includes a substrate, an electronic component mounted on a principal surface of the substrate, an insulating layer that covers the principal surface of the substrate and the electronic component and that includes a recessed portion in a principal surface thereof, and a shielding layer that covers the principal surface of the insulating layer and an inner surface of the recessed portion, the shielding layer being made of a conductive material.

According to another preferred embodiment of the present invention, a method of manufacturing the circuit module includes a first step of preparing a substrate, a second step of mounting a plurality of electronic components on a principal surface of the substrate, a third step of forming an insulating layer so as to cover the principal surface of the substrate and the plurality of electronic components, a fourth step of forming a recessed portion in a principal surface of the insulating layer, and a fifth step of forming a shielding layer by applying a conductive material on the principal surface of the insulating layer and an inner surface of the recessed portion.

According to various preferred embodiments of the present invention, satisfactory isolation characteristics are obtained from a circuit module and a method of manufacturing the same.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an external perspective view of a circuit module according to a preferred embodiment of the present invention.

FIG. 2 is an illustration of the circuit module in FIG. 1 seen through from above.

FIG. 3 illustrates a cross-sectional structure of the circuit module taken along X-X in FIG. 2.

FIGS. 4A-4E includes cross-sectional views that illustrate steps for manufacturing the circuit module.

FIG. 5 illustrates a cross-sectional structure of a circuit module according to a first variation of a preferred embodiment of the present invention.

FIG. 6 illustrates a cross-sectional structure of a circuit module according to a second variation of a preferred embodiment of the present invention.

FIG. 7 illustrates a cross-sectional structure of a circuit module according to a third variation of a preferred embodiment of the present invention.

FIG. 8 illustrates a cross-sectional structure of a circuit module according to a fourth variation of a preferred embodiment of the present invention.

FIG. 9 illustrates a cross-sectional structure of a circuit module according to a fifth variation of a preferred embodiment of the present invention.

FIG. 10 illustrates a cross-sectional structure of a circuit module according to a sixth variation of a preferred embodiment of the present invention.

FIG. 11 is an illustration of a circuit module according to a seventh variation of a preferred embodiment of the present invention seen through from above.

FIG. 12 illustrates a cross-sectional structure of a circuit module described in Japanese Unexamined Patent Application Publication No. 2008-288610.

### DETAILED DESCRIPTION OF THE PREFERRED EMBODIMENTS

A circuit module and a method of manufacturing the same according to various preferred embodiments of the present invention will be described below with reference to the drawings.

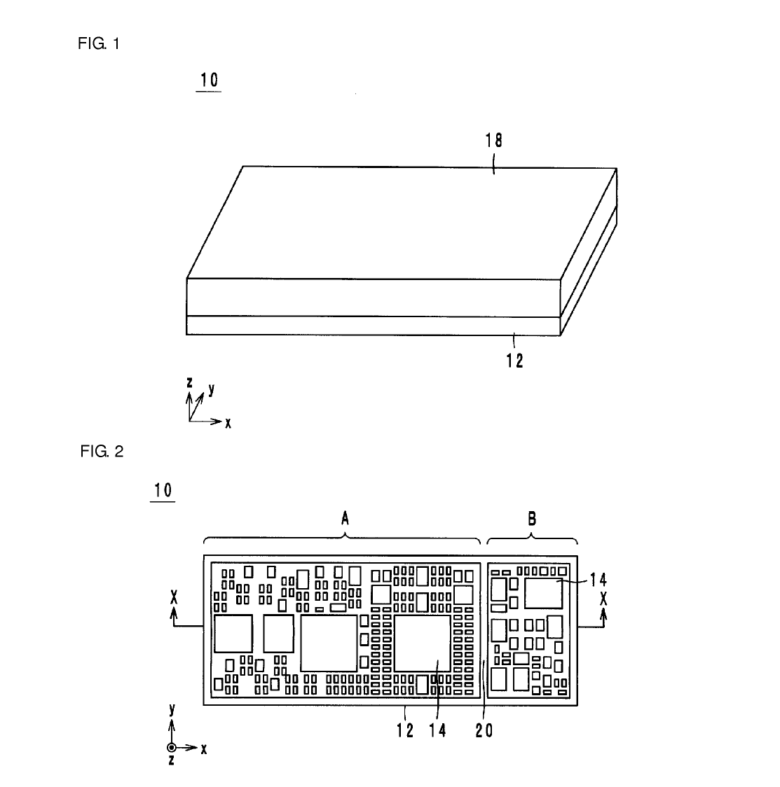

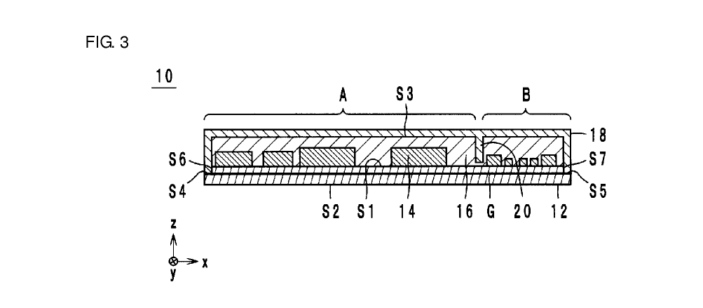

The configuration of a circuit module according to a preferred embodiment of the present invention will be described below with reference to the drawings. FIG. 1 is an external perspective view of a circuit module 10 according to a preferred embodiment of the present invention. FIG. 2 is an illustration of the circuit module 10 in FIG. 1 seen through from above. FIG. 3 illustrates a cross-sectional structure of the circuit module 10 taken along X-X in FIG. 2. In the following description, the height direction in the circuit module 10, which has a rectangular or substantially rectangular parallelepiped shape, is defined as the z-axis direction. The direction of the long side of the circuit module 10 seen in plan view from the z-axis direction is defined as the x-axis direction, and the direction of the short side is defined as the y-axis direction. The x axis, y axis, and z axis are perpendicular to one another.

The circuit module 10 includes a circuit substrate 12, electronic components 14 (see FIGS. 2 and 3), an insulating layer 16 (see FIGS. 2 and 3), and a shielding layer 18, as illustrated in FIGS. 1 to 3. The circuit substrate 12 is a multilayer printed substrate having a rectangular or substantially rectangular shape and including principal surfaces S1 and S2. Thus, the circuit substrate 12 is preferably formed by stacking of a plurality of rectangular or substantially rectangular insulating layers (for example, dielectric ceramic layers). The principal surface S1 is positioned in the positive z-axis direction with respect to the principal surface S2.

The circuit substrate 12 includes circuits and outer electrodes. The circuits are incorporated in the circuit substrate 12. The outer electrodes are disposed on the principal surfaces S1 and S2. In FIG. 3, of the circuits incorporated in the circuit substrate 12, only a ground conductor G is illustrated. The outer electrodes are omitted in FIG. 3.

The electronic components 14 can be, for example, semiconductor integrated circuits, chip-type electronic components, or other components and are mounted on the principal surface S1 of the circuit substrate 12, as illustrated in FIGS. 2 and 3. In FIGS. 2 and 3, only representative electronic components 14 are indicated by reference numerals to prevent complicating the drawings.

As illustrated in FIGS. 2 and 3, the circuit substrate 12 includes a plurality of circuit blocks A and B. The circuit block A is next to the circuit block B in the negative x-axis direction of the circuit block B. The circuit block A preferably includes the electronic components 14 and circuit substrate 12 present in the circuit block A and serves a predetermined function. Similarly, the circuit block B preferably includes the electronic components 14 and circuit substrate 12 present in the circuit block B and serves a predetermined function. The function served by the circuit block A differs from the function served by the circuit block B. Examples of the combination of the circuit blocks A and B can include a combination of a transmission block and a reception block in wireless communication and a combination of a block including a DC-to-DC converter and a block that processes a baseband signal.

The insulating layer 16 is made of an insulating resin (for example, epoxy resin) and covers the principal surface S1 of the circuit substrate 12 and each of the electronic components 14, as illustrated in FIGS. 1 and 2. The insulating layer 16 protects the principal surface S1 of the circuit substrate 12 and the electronic component 14 and insulates the electronic component 14 and the shielding layer 18, which is described below, from each other.

A groove 20 is disposed in a principal surface S3 of the insulating layer 16, the principal surface S3 is positioned in the positive z-axis direction, and the groove 20 is arranged such that the principal surface S3 is recessed in the negative z-axis direction, as illustrated in FIG. 3. More specifically, the groove 20 is disposed at the border between the circuit blocks A and B, as illustrated in FIG. 2. The circuit blocks A and B are aligned in the x-axis direction in the circuit module 10. Thus, the groove 20 extends along the y-axis direction between the circuit blocks A and B when seen in plan view from the z-axis direction. The bottom of the groove 20 is positioned above the principal surface S1 of the circuit substrate 12 in the z-axis direction, as illustrated in FIG. 3. In this way, the insulating layer 16 in the circuit block A and the insulating layer 16 in the circuit block B are connected to each other in the negative z-axis direction with respect to the groove 20.

The shielding layer 18 is preferably made of a conductive resin that covers the principal surface S3 of the insulating layer and the inner surface of the groove 20. In the circuit module 10, the groove 20 is filled with the conductive resin. The shielding layer 18 covers the side surfaces of the insulating layer 16 on both sides in the x-axis direction and those on both sides in the y-axis direction, as illustrated in FIGS. 2 and 3.

The shielding layer 18 further covers a portion of the side surfaces on both sides of the circuit substrate 12 in the x-axis direction and those in the y-axis direction, as illustrated in FIG. 3. Specifically, there is a step on both sides of the principal surface S1 of the circuit substrate 12 in the x-axis direction and those in the y-axis direction, as illustrated in FIG. 3. That is, surfaces S4 and S5 formed by cutting a portion of both ends in the x-axis direction and both ends in the y-axis direction of the principal surface S1 are disposed such that they are positioned in the negative z-axis direction with respect to the principal surface S1 and face in the positive z-axis direction, as illustrated in FIG. 3. The surfaces S4 and S5 extend along the short side of the circuit substrate 12 in the negative x-axis direction and that in the positive x-axis direction, respectively. A surface S6 is disposed so as to connect the principal surface S1 and the surface S4, and a surface S7 is disposed so as to connect the principal surface S1 and the surface S5. The surfaces S6 and S7 are surfaces perpendicular or substantially perpendicular to the x-axis direction. There is no step between the surface S6 and the side surface of the insulating layer 16 in the negative x-axis direction, and that is, they are flush with each other. Similarly, there is no step between the surface S7 and the side surface of the insulating layer 16 in the positive x-axis direction, and that is, they are flush with each other. The structure of both ends of the circuit substrate 12 in the y-axis direction is similar to the structure of both ends of the circuit substrate 12 in the x-axis direction, and the description thereof is omitted.

The ground conductor G is exposed from the circuit substrate 12 at these surfaces S4 and S5, as illustrated in FIG. 3. The shielding layer 18 covers the surfaces S4 to S7. In this way, the shielding layer 18 and the ground conductor G are connected to each other. That is, a ground potential is applied to the ground conductor G. As a result, the shielding layer 18 prevents radiation of noise to outside the circuit module 10 and entry of noise into the circuit module 10.

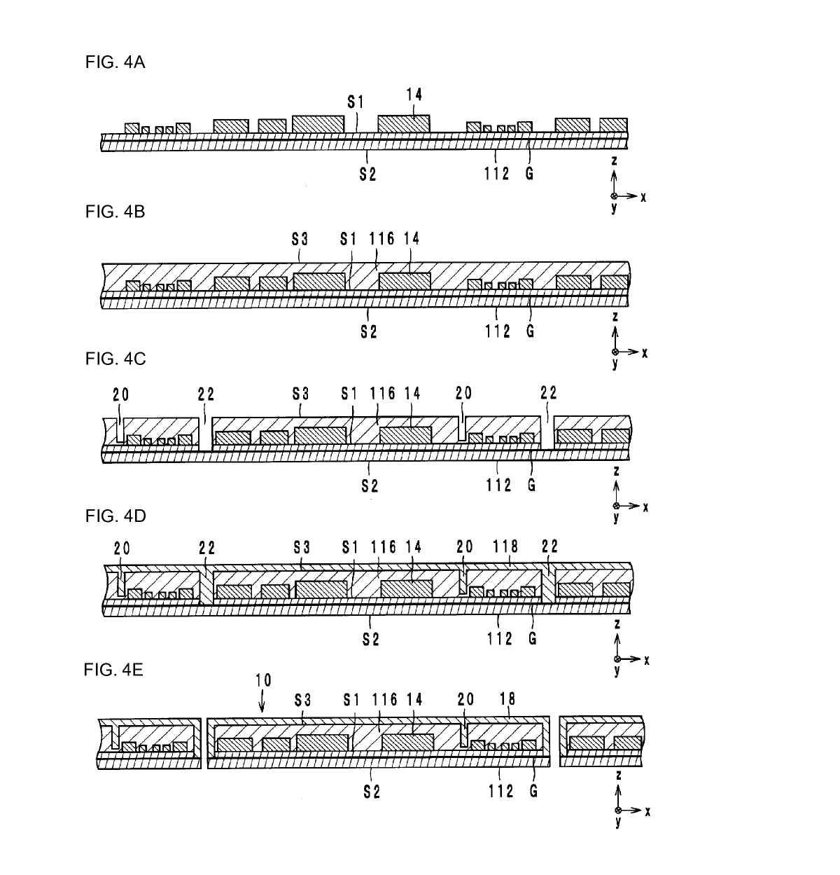

Next, a non-limiting example of a method of manufacturing the circuit module 10 will be described with reference to the drawings. FIGS. 4A-4E includes cross-sectional views that illustrate steps for manufacturing the circuit module 10.

First, a mother substrate 112 illustrated in FIG. 4A is prepared. The mother substrate 112 is an assembly substrate in which a plurality of circuit substrates 12 are arranged in a matrix and can be, for example, a multilayer resin substrate or a multilayer ceramic substrate. The mother substrate 112 may be prepared by being produced or may also be prepared by purchase of a finished product. The mother substrate 112 is known, and the description of a method of manufacturing the mother substrate 112 is omitted.

Next, as illustrated in FIG. 4A, a plurality of electronic components 14 are mounted on the principal surface S1 of the mother substrate 112 by soldering. The electronic components 14 may also be mounted by wire bonding or using solder bumps.

Next, as illustrated in FIG. 4B, an insulating layer 116 is formed so as to cover the principal surface S1 of the mother substrate 112 and the plurality of electronic components 14. Specifically, an insulating resin is applied on the principal surface S1 of the mother substrate 112 and the plurality of electronic components 14 by the use of a dispenser. Then, the insulating resin is heated and cured. The insulating layer 116 may also be formed by application of the resin by a method other than that using the dispenser.

Next, as illustrated in FIG. 4C, grooves 20 and 22 are provided in the principal surface S3 of the insulating layer 116. Specifically, a dicing saw is moved in the y-axis direction along the border between the circuit blocks A and B. At this time, the dicing saw does not reach the mother substrate 112. In this way, the grooves 20 are formed. The dicing saw is also moved along cut lines for use in cutting the mother substrate 112 into the individual circuit substrates 12. At this time, the dicing saw reaches the ground conductor G of the mother substrate 112. In this way, the grooves 22, each of which has a depth greater than that of the groove 20, are formed. The ground conductor G is exposed at the bottom of each of the grooves 22.

Next, as illustrated in FIG. 4D, a shielding layer 118 is formed by application of a conductive resin on the principal surface S3 of the insulating layer 116 and the inner surfaces of the grooves 20 and 22. The application of the conductive resin is preferably performed by spin coating. Specifically, the mother substrate 112 is placed on a turn table, and the mother substrate 112 is rotated at a predetermined angular velocity. A slurry conductive resin is dripped on the center of the insulating layer 116. In this way, the conductive resin is thinly spread over the principal surface S3 of the insulating layer 116 by centrifugal force. The shielding layer 118 may also be formed using conductive paste or may also be formed by vacuum film forming, such as sputtering or vapor deposition.

Next, as illustrated in FIG. 4E, the mother substrate 112 with the insulating layer 116 and the shielding layer 118 being formed thereon is divided, and a plurality of circuit modules 10 are obtained. Specifically, a dicing saw having a width narrower than the width of the dicing saw used in forming the grooves 22 is moved along cut lines to cut the mother substrate 112. Through the above-described steps, the circuit module 10 illustrated in FIGS. 1 to 3 is completed.

According to the above-described circuit module 10 and method of manufacturing the same, satisfactory isolation characteristics are obtainable between the circuit blocks A and B. More specifically, the circuit blocks A and B are aligned in the x-axis direction in the circuit module 10. The groove 20 extends in the y-axis direction between the circuit blocks A and B when seen in plan view from the z-axis direction. That is, the groove 20 is disposed on the border between the circuit blocks A and B. The groove 20 is filled with the conductive resin forming the shielding layer 18. Because of this, noise and magnetic fields radiated from the circuit block A are absorbed in the conductive resin within the groove 20 (that is, shielding layer 18) and are less likely to reach the circuit block B. Similarly, because noise and magnetic fields radiated from the circuit block B are grounded through the conductive resin within the groove 20 (that is, shielding layer 18), they are less likely to reach the circuit block A. Consequently, according to the circuit module 10 and the method of manufacturing the same, satisfactory isolation characteristics are obtainable between the circuit blocks A and B.

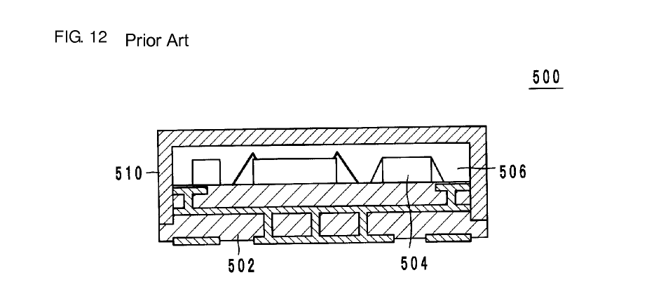

According to the above-described circuit module 10 and the method of manufacturing the same, the occurrence of warps in the circuit module 10 is significantly reduced or prevented. More specifically, in the traditional circuit module 500 illustrated in FIG. 12, the entire surface of the principal surface of the substrate 502 is covered with the sealing resin layer 506. In this case, at the time of cure of the sealing resin layer 506, the sealing resin layer 506 is more shrunk than the substrate 502. Thus the substrate 502 is warped such that its central portion projects downward. In particular, when the circuit module 500 is used in a wireless communication module, because it incorporates a plurality of circuit blocks, the number of electronic components being mounted is large, and the size of the substrate 502 is large. When the size of the substrate 502 is large, the amount of sealing resin is also large, the amount of shrinkage of the sealing resin layer 506 is also large, and additionally, the stiffness of the substrate 502 is reduced and the substrate 502 is thus likely to be easily deformed. Accordingly, the circuit module 500 is largely warped. As a result, when the circuit module 500 is mounted on the mother substrate, a faulty connection occurs.

For the circuit module 10, the insulating layer 16 includes the groove 20. At the time of cure of the insulating layer 16, the insulating layer 16 does not substantially shrink in the portion where the groove 20 is disposed. Accordingly, separate shrinkages of the insulating layer 16 occur in the circuit blocks A and B in the circuit module 10, and separate warps of the circuit substrate 12 occur in the circuit blocks A and B. When the circuit module 10 and the circuit module 500 have the same size, the amount of shrinkage of the insulating layer 16 in each of the circuit blocks A and B is smaller than that of the sealing resin layer 506 in the circuit module 500. When the circuit module 10 and the circuit module 500 have the same size, because each of the circuit blocks A and B is smaller than the circuit module 500, each of the circuit blocks A and B is less likely to be deformed than the circuit module 500. Accordingly, only a warp smaller than that in the circuit module 500 occurs in each of the circuit blocks A and B in the circuit module 10. As a result, warps occurring in the circuit module 10 as a whole are smaller than warps occurring in the circuit module 500 as a whole.

In the circuit module 10, the groove 20 is disposed in only the insulating layer 16 and not disposed in the circuit substrate 12. This can prevent the inclusion of the groove 20 from decreasing the strength of the circuit substrate 12.

In the circuit module 10, the bottom of the groove 20 is positioned in the positive z-axis direction with respect to the principal surface S1 of the circuit substrate 12. Accordingly, in the circuit module 10, wiring and other elements can also be formed in a region in the negative z-axis direction with respect to the groove 20.

A circuit module according to a first variation of a preferred embodiment of the present invention will be described below with reference to a drawing. FIG. 5 illustrates a cross-sectional structure of a circuit module 10a according to the first variation.

In the circuit module 10a, the bottom of the groove 20 coincides with the principal surface S1 of the circuit substrate 12. The groove 20 is filled with the conductive resin defining the shielding layer 18. Thus, the isolation characteristics between the circuit blocks A and B in the circuit module 10a are more satisfactory than those in the circuit module 10.

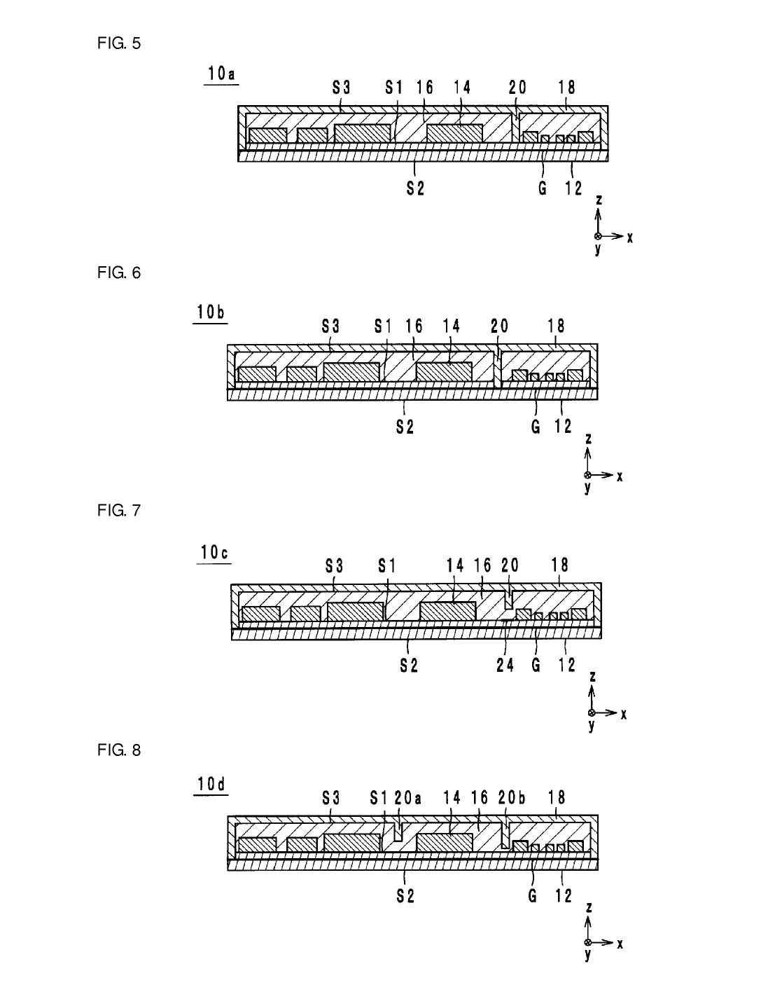

A circuit module according to a second variation of a preferred embodiment of the present invention will be described below with reference to a drawing. FIG. 6 illustrates a cross-sectional structure of a circuit module 10b according to the second variation.

In the circuit module 10b, the bottom of the groove 20 coincides with the ground conductor G in the circuit substrate 12. That is, the depth of the groove 20 in the circuit module 10b is equal to or larger than the thickness of the insulating layer 16. The groove 20 is filled with the conductive resin defining the shielding layer 18. Thus, the isolation characteristics between the circuit blocks A and B in the circuit module 10b are more satisfactory than those in the circuit module 10. In addition, because the shielding layer 18 is in contact with the ground conductor G, the potential of the shielding layer 18 is nearer to the ground potential.

A circuit module according to a third variation of a preferred embodiment of the present invention will be described below with reference to a drawing. FIG. 7 illustrates a cross-sectional structure of a circuit module 10c according to the third variation.

In the circuit module 10c, the circuit substrate 12 includes a conductive layer 24 facing the bottom of the groove 20. The groove 20 is filled with the conductive resin, and it is connected to the ground electrode in the circuit substrate 12 and is thus at a ground potential. Thus, a capacitor whose one electrode is grounded is provided between the conductive layer 24 and the bottom of the groove 20. Thus, a ground capacitor that would be disposed in the circuit substrate 12 can be arranged outside the circuit substrate 12, and one capacitor in the circuit substrate 12 becomes unnecessary. As a result, empty space is present in the circuit substrate 12, and another circuit element can be arranged in that space. Accordingly, the circuit substrate 12 in the circuit module 10c has a high degree of freedom in the design.

A circuit module according to a fourth variation of a preferred embodiment of the present invention will be described below with reference to a drawing. FIG. 8 illustrates a cross-sectional structure of a circuit module 10d according to the fourth variation.

In the circuit module 10d, a plurality of grooves 20a and 20b are disposed in the principal surface S3 of the insulating layer 16. The grooves 20a and 20b have different depths. That is, the number of the grooves 20 in the insulating layer 16 may be more than one, and the plurality of grooves 20 may have different depths. In this case, the depth of the grooves 20 varies depending on the position of the groove 20. Specifically, the depth of the groove 20 between circuit blocks at which the isolation characteristics are required to be relatively more satisfactory is set at a relatively large value. Examples of the circuit blocks at which the isolation characteristics are required to be relatively more satisfactory can include a circuit block that includes an electronic component that causes a magnetic field in the vicinity of a coil, an isolator, and other elements. The depth of the groove 20 between circuit blocks at which the isolation characteristics are not required to be relatively more satisfactory is set at a relatively small value.

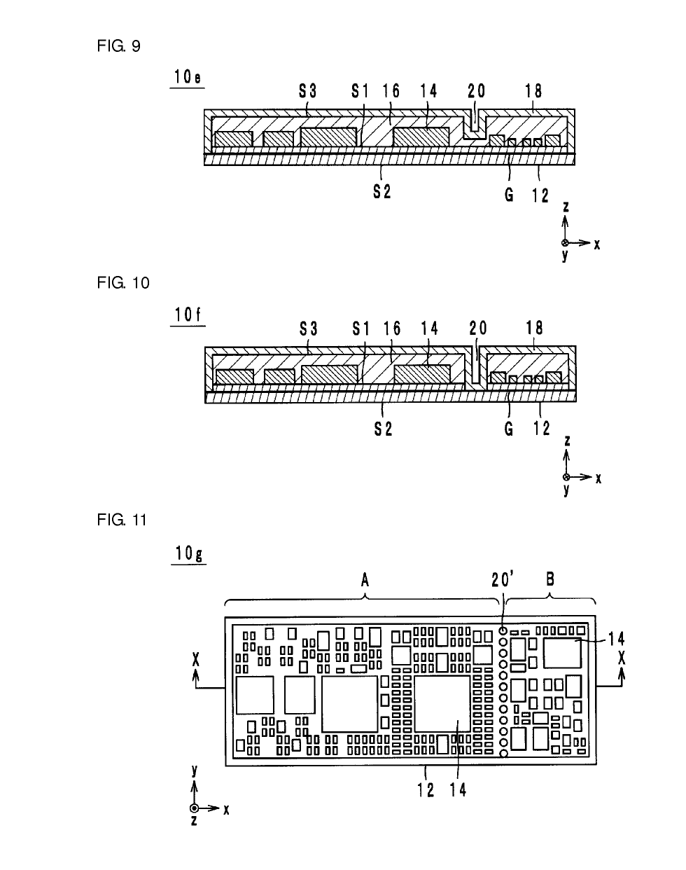

A circuit module according to a fifth variation of a preferred embodiment of the present invention will be described below with reference to a drawing. FIG. 9 illustrates a cross-sectional structure of a circuit module 10e according to the fifth variation.

In the circuit module 10e, the groove 20 is not filled with a conductive resin, and the inner surface of the groove 20 is covered with a conductive resin. Accordingly, a space where the conductive resin is absent exists inside the groove 20. Thus, the occurrence of warps in the circuit module 10e can be reduced more effectively than that in the circuit module 10. As illustrated in FIG. 9, the arrangement in which the groove 20 deviates from the center of the circuit module 10e in the x-axis direction toward the positive direction enables the orientation of the circuit module 10e to be easily identified at the time of mounting the circuit module 10e on the mother substrate or other elements.

A circuit module according to a sixth variation of a preferred embodiment of the present invention will be described below with reference to a drawing. FIG. 10 illustrates a cross-sectional structure of a circuit module 10f according to the sixth variation.

In the circuit module 10f, the groove 20 is not filled with a conductive resin, and the inner surface of the groove 20 is covered with a conductive resin. Accordingly, space where the conductive resin is absent exists inside the groove 20. Thus, the occurrence of warps in the circuit module 10f can be reduced more effectively than that in the circuit module 10.

Additionally, in the circuit module 10f, the bottom of the groove 20 coincides with the ground conductor G in the circuit substrate 12. That is, the depth of the groove 20 in the circuit module 10f is equal to or larger than the thickness of the insulating layer 16. Thus, the isolation characteristics between the circuit blocks A and B in the circuit module 10f are more satisfactory than those in the circuit module 10. Moreover, because the shielding layer 18 is in contact with the ground conductor G, the potential of the shielding layer 18 is nearer to the ground potential.

A circuit module according to a seventh variation of a preferred embodiment of the present invention will be described below with reference to a drawing. FIG. 11 is an illustration of a circuit module 10g according to the seventh variation seen through from above.

In the circuit modules 10 and 10a to 10f, the groove(s) 20 is disposed in the principal surface S3 of the insulating layer 16. However, in place of the groove(s) 20, openings 20′ may be disposed in the principal surface S3 of the insulating layer 16, as illustrated in FIG. 11. That is, recessed portions, such as the openings 20′, may be disposed in the principal surface S3 of the insulating layer 16, and the inner surfaces of the recessed portions are covered with the conductive resin defining the shielding layer 18.

A circuit module according to the present invention is not limited to the circuit modules 10 and 10a to 10g according to the above-described preferred embodiments and modifications thereof, and changes can be made within the scope thereof.

The shielding layer 18 is described above as preferably being made of a conductive resin. However, the shielding layer 18 may be made of any conductive material. For example, the shielding layer 18 may be formed by metal plating or may also be formed by the application of a resin that contains carbon.

As described above, various preferred embodiments of the present invention are useful in a circuit module and a method of manufacturing the same and, in particular, are excellent in that satisfactory isolation characteristics are obtainable.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1-9. (canceled)

10. A circuit module comprising:
a substrate;
an electronic component mounted on a principal surface of the substrate;
an insulating layer that covers the principal surface of the substrate and the electronic component and that includes a recessed portion in a principal surface thereof; and
a shielding layer that covers the principal surface of the insulating layer and an inner surface of the recessed portion; wherein
the shielding layer is made of a conductive material.

11. The circuit module according to claim 10, wherein the recessed portion is a groove.

12. The circuit module according to claim 10, wherein the recessed portion has a depth equal to or larger than a thickness of the insulating layer.

13. The circuit module according to claim 10, wherein the substrate includes a ground conductive layer, and the shielding layer is connected to the ground conductive layer.

14. The circuit module according to claim 10, wherein the recessed portion comprises a plurality of recessed portions in the principal surface of the insulating layer, and the plurality of recessed portions have a plurality of different depths.

15. The circuit module according to claim 10, wherein the substrate includes a conductive layer that faces the conductive material at a bottom of the recessed portion.

16. The circuit module according to claim 10, wherein the substrate includes a plurality of circuit blocks having different functions, and the recessed portion is disposed at a border between the plurality of circuit blocks.

17. The circuit module according to claim 10, wherein the substrate is a multilayer printed substrate including a plurality of insulating sheets stacked on each other.

18. The circuit module according to claim 10, wherein the electronic component is one of a semiconductor integrated circuit and a chip-type electronic component.

19. The circuit module according to claim 10, wherein the recessed portion is a groove, a bottom of the groove coincides with the principal surface of the circuit substrate, and the groove is filed with a conductive resin the defines the shielding layer.

20. The circuit module according to claim 13, wherein the recessed portion is a groove, a bottom of the groove coincides with the ground conductive layer, and the groove is filed with a conductive resin the defines the shielding layer.

21. The circuit module according to claim 10, wherein the recessed portion is a groove, a conductive layer is arranged to face a bottom of the groove, and the groove is filed with a conductive resin the defines the shielding layer.

22. The circuit module according to claim 10, wherein the recessed portion includes a plurality of grooves disposed in the principal surface of the insulating layer, and the plurality of grooves have different depths.

23. The circuit module according to claim 10, wherein the recessed portion is a groove including an inner surface covered with a conductive resin.

24. The circuit module according to claim 13, wherein the recessed portion is a groove, a bottom of the groove coincides with the ground conductive layer, and the groove is covered by a conductive resin.

25. The circuit module according to claim 10, wherein the recessed portion includes a plurality of openings disposed in the principal surface of the insulating layer, and the plurality of recessed portions are covered by a conductive resin that defines the shielding layer.

26. The circuit module according to claim 10, wherein the shielding layer is made of one of a conductive resin, a metal plating and a resin containing carbon.

27. A method of manufacturing a circuit module, the method comprising:
a first step of preparing a substrate;
a second step of mounting a plurality of electronic components on a principal surface of the substrate;
a third step of forming an insulating layer so as to cover the principal surface of the substrate and the plurality of electronic components;
a fourth step of forming a recessed portion in a principal surface of the insulating layer; and
a fifth step of forming a shielding layer by applying a conductive material on the principal surface of the insulating layer and an inner surface of the recessed portion.

28. The method according to claim 27, wherein, in the fourth step, a groove is formed as the recessed portion in the principal surface of the insulating layer by using a dicing saw.
